(19) United States
(12) Patent Application Publication
(10) Pub. No.: US 2016/0359104 A1
(43) Pub. Date: Dec. 8, 2016

(54) ALLOY CRYSTALLISATION METHOD

(71) Applicant: The University of York, York (GB)

(72) Inventors: Luke Roger Fleet, London (GB); Atsufumi Hirohata, York (GB); James Thomas Sagar, Twickenham (GB)

(73) Assignee: The University of York, York (GB)

(21) Appl. No.: 15/117,504

(22) PCT Filed: Feb. 12, 2015
(86) PCT No.: PCT/GB2015/050385

§ 371 Date: Aug. 9, 2016

(30) Foreign Application Priority Data
Feb. 12, 2014 (GB) 1402399.8

(51) Int. Cl. H01L 43/10; C23C 14/24; C23C 14/14; H01F 41/30; H01L 43/12; H01F 10/12; H01F 10/32; C23C 14/58; H01L 43/08

(52) U.S. Cl. CPC H01L 43/10; C23C 14/5806; C23C 14/24; C23C 14/14; H01L 43/08; H01L 43/12; H01F 10/12; H01F 10/32; H01F 41/302

(57) ABSTRACT

A crystallisation method for an alloy film such as a Co-based ternary Heusler-alloy is described having the steps of: providing a substrate; depositing a layer of the alloy film to be crystallised onto the substrate using a physical vapour deposition process to a depth of up to a few hundred nm; optionally depositing a capping layer thereon; heating the deposited film at an annealing temperature below 300° C. and for example of around 200° C. to 300° C. to effect crystallisation of the alloy film layer. The method is in particular applied to the in the deposition and annealing in situ of an alloy film in or on a semiconductor device for example as a functional film in or on such a device and in particular to the deposition and annealing in situ of a highly-spin-polarised ferromagnetic thin film on a semiconductor or spintronic device.

The invention relates to a deposition and crystallisation method for an alloy film. The invention relates in particular to a deposition and crystallisation method for an alloy film having a face-centred cubic crystal structure. The invention relates in particular to a deposition and crystallisation method for a ternary Heusler-alloy film.

The invention in particular relates to a method for the deposition and crystallisation of an alloy film as a functional thin film on a semiconductor or spintronic device, and for example as a ferromagnetic thin film on a semiconductor memory device and preferably also to the in situ annealing of such a thin film in situ as part of the device.

One type of important functional film is a ferromagnetic film which finds application in a range of memory devices for example. Half-metallic Alloys (I. Galanakis & P. H. Dederichs, eds) (Springer, 2005) describes highly-spin-polarised ferromagnetic film. These films, which ideally can reach 100% spin polarisation, could have huge implications for future spintronic devices as they offer the potential for efficient spin-currents to be electrically injected into conventional semiconductors, which could allow for the unification of semiconductor and magnetic recording technologies.

A potentially interesting ferromagnetic material in this regard is a Heusler alloy. Heusler alloys are ferromagnetic ternary or higher order alloys that form a Heusler phase intermetallic structure with particular composition and face-centred cubic crystal structure. They are ferromagnetic even though the constituting elements are not. Heusler alloys are one of the leading candidate material classes for achieving high spin polarisation.

Heusler-alloy films and in particular, Co-based Heusler-alloy films have been theoretically predicted to show the half-metallicity at and above room temperature (RT) and have been experimentally investigated widely. Experimental reports have already shown that these alloys exhibit extremely high spin-polarisation, approaching 100%, in bulk samples or in thin films at low temperatures, highlighting the potential of these systems. The main problem, however, is that in order to create the high degree of structural ordering required to lead to such desirable magnetic properties, extremely high annealing temperatures are required, typically between 500° C. (thin films) to 1000° C. (bulk). Such high temperatures are incompatible with conventional semiconductor and magnetic recording technologies, with processing in situ in or on semiconductor devices such as memory devices and processors, where processing temperatures of around 200° C. or 250° C. are more applicable.

It is desirable to develop a crystallisation process for an alloy film that mitigates these disadvantages and in particular that allows deposition of an alloy film that can be crystallised at a lower annealing temperatures compatible with their processing in situ in or on semiconductor devices for example to facilitate their use as functional films in or on such devices.

In accordance with the invention in a first aspect, a crystallisation method for an alloy film comprises the steps of:

providing a substrate;

depositing a layer of the alloy film to be crystallised onto the substrate using a physical vapour deposition process to a depth of up to a few hundred nm;

optionally depositing a capping or other subsequent layer(s) thereon;

heating the deposited film at an annealing temperature below 300° C. and for example of around 200° C. to 300° C. to effect crystallisation of the alloy film layer.

The invention at its most general relies upon the realisation that a thin film generally amorphous layer that is physically deposited in the manner described can be annealed to effect crystallisation at relatively lower temperatures than has hitherto been supposed over practical timescales.

Although the method is not limited by any particular theory of the mechanism at work during the low-temperature annealing process, experimental observations are discussed and possible mechanisms explored herein.

Detailed crystallisation processes and their control have not hitherto been fully understood due to the lack of observation tools available during crystallisation with the required atomic resolution. Atomic-resolution observation and analysis on the crystallisation processes have been significant challenges in materials science and condensed-matter physics. Current models to describe the crystallisation processes have been developed phenomenologically. These models suggest that crystallisation may favour particular axes, which have potential to reduce the crystallisation energy.

In the examples described herein a crystallisation process for a face-centred cubic ternary alloy is described, whose initial nucleation is analysed by as small as 27 unit cells, using a recently developed observation technique with in situ annealing. The crystallisation occurs preferentially in the <111>crystalline directions via a 2-dimensional (2D) layer-by-layer growth mode resulting in grains with [110] surface normal and [111] plane facets. This process is found to reduce the crystallisation energy substantially, in some instances by more than 50% when compared to bulk samples whilst still leading to the growth of highly ordered grains with a high degree of spin-polarisation.

This layer-by-layer growth appears to reduce the crystallisation energy and facilitates the low-temperature anneal in accordance with the method of the invention. In particular it allows the application of the method of the invention for the deposition and anneal in situ of an alloy film in or on a semiconductor or spintronic device for example as a functional film in or on such a device. Such reduction in the temperature of the crystallisation anneal is essential for the implementation of the method into the current chip and memory industry.

It is important to emphasise that the crystallisation mechanism exploited by the method of the invention appears to be a nucleation and crystallisation mechanism within the alloy layer itself. The substrate is not selected to be and does not function as a seed crystal for the process. The substrate therefore need not be limited by such considerations, but can be selected for its functionality in any resultant as fabricated device of which it and the alloy layer may be intended to form a part.

The invention is characterised by subjecting the layer of the alloy film to an annealing temperature of below 300° C. and for example around 200° C. to 300° C. This enables nucleation and growth of a structured layer within practical timescales, and preferably within 24 hours. Typically annealing times are between 5 minutes and 10 hours. Thus the layer is preferably heated to a temperature of below 300° C. and for example around 200° C. to 300° C., and more preferably below 250° C. and for example around 200° C. to 250° C., for a time period of between 5 minutes and 10 hours. For practical purposes annealing times of at least 60 minutes and for example at least 100 minutes are preferred.

The layer in accordance with the invention is deposited as a thin film using a physical vapour deposition process to a depth of up to a few hundred nm, for example up to 250 nm. Thinner films may be preferred, for example up to 100 nm, in a preferred case 25 nm and in a more preferred case no more than 20 nm. A typical minimum thickness may be 3 nm and in a preferred case 5 nm.

The layer of the alloy film to be crystallised is deposited onto the substrate using a physical vapour deposition process, typically with an initially substantially amorphous structure. A preferred physical vapour deposition process is sputter deposition. For example, the layer of the alloy film to be crystallised may be sputter deposited by sputtering from a stoichiometric or close to stoichiometric target. A preferred physical vapour deposition temperature is below 50° C. and for example at or about room temperature.

Optionally a capping layer may be deposited on top of the layer of the alloy film prior to the annealing step, for example using a similar or dissimilar physical vapour deposition process. A preferred capping layer is a generally inert metallic layer, for example comprising one or more noble metals or alloys thereof. A suitable capping layer thickness is below 5 nm and for example about 2 nm.

The deposited layer of the alloy film is annealed in situ on a substrate. In a preferred case the deposited layer and the substrate may be heated together, for example in the substrate is heated and for example in that the substrate is supported on a suitable heating stage.

Conveniently, the substrate comprises a semiconductor or spintronic device material on which the deposited layer is intended to constitute a functional film in a fabricated device once crystallised in accordance with the method of the invention.

The invention finds particular application as a deposition and crystallisation process for an alloy film having a face-centred cubic crystal structure. Accordingly, the alloy constituting the deposited layer of the alloy film to be crystallised is preferably selected to be a material that crystallises with a face-centred cubic crystal structure.

In a preferred case the alloy is at least a ternary alloy.

In a preferred case, the alloy constituting the deposited layer of the alloy film is selected to comprise an electromagnetically functional thin film when crystallised and for example a ferromagnetic thin film. For example the film when crystallised comprises a highly-spin-polarised, and ideally half-metallic (100% spin-polarised), ferromagnetic film.

The invention relates in particular to a crystallisation process for a ternary Heusler-alloy film. Accordingly, the alloy constituting the deposited layer of the alloy film to be crystallised is preferably selected from the group comprising ternary Heusler-alloys and higher order alloys derived therefrom, for example Co-based ternary Heusler-alloys. Suitable Co-based ternary Heusler-alloys include Co₂MnAl, Co₂MnSi, Co₂MnGa, Co₂MnGe, Co₂FeSi, Co₂FeAl etc. and their higher order alloys by substituting the constituent atoms with the other atoms.

The method is in particular applied to the in the deposition and annealing in situ of an alloy film in or on a semiconductor or spintronic device for example as a functional film in or on such a device and in particular to the deposition and annealing in situ of a highly-spin-polarised ferromagnetic thin film on a semiconductor or spintronic device.

Thus, in accordance with the invention in a second more complete aspect a method of fabrication of an alloy layer on a semiconductor or spintronic device and in particular of fabrication of a functional thin film on a semiconductor or spintronic device comprises the steps of:

providing a substrate of a semiconductor or spintronic device material;

depositing and crystallising thereon an alloy layer and in particular a functional thin film by the method of the first aspect of the invention.

Other preferred features of this aspect of the invention will be understood by analogy from the description of the first aspect.

In accordance with a further aspect of the invention, a semiconductor device comprises an alloy layer and in particular a functional thin film that has been deposited and crystallised thereon by the method of the first aspect/fabricated by the method of the second aspect.

Other preferred features of this aspect of the invention will be understood by analogy from the description of the first aspect.

The invention will now be described by way of example only with reference to the accompanying drawings, in which:

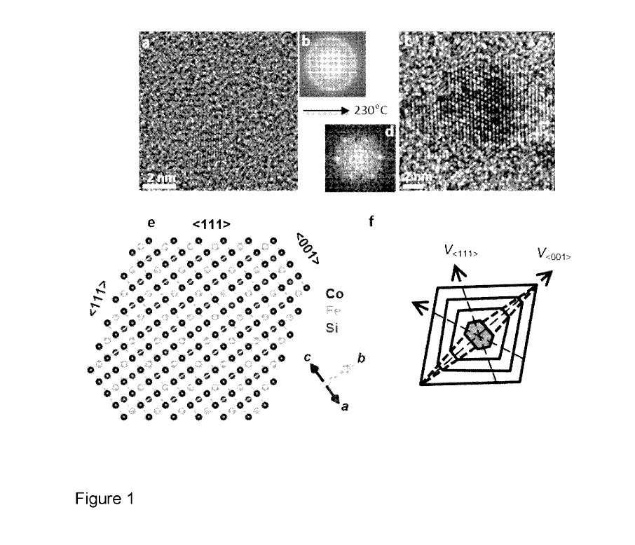

FIG. 1 shows various experimental and modelled data to illustrate Co2FeSi grains produced in an example embodiment of the invention;

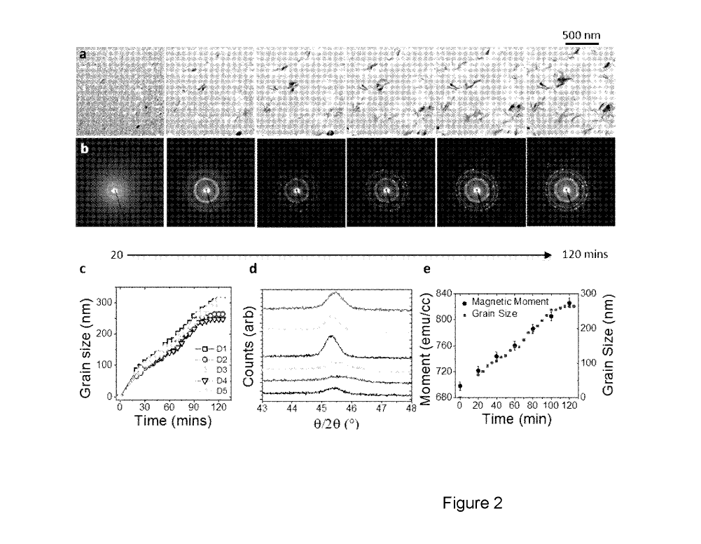

FIG. 2 shows TEM images and selected area electron diffraction (SAED) patterns during the crystallisation from 20 minutes to 120 minutes with 20 minute steps at 235° C. additional modelling;

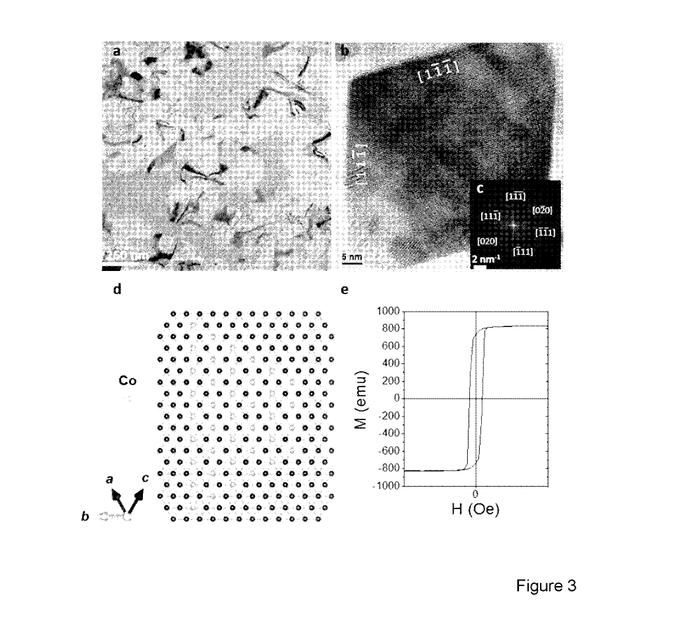

FIG. 3 shows various properties of low temperature annealed Co₂FeSi films;

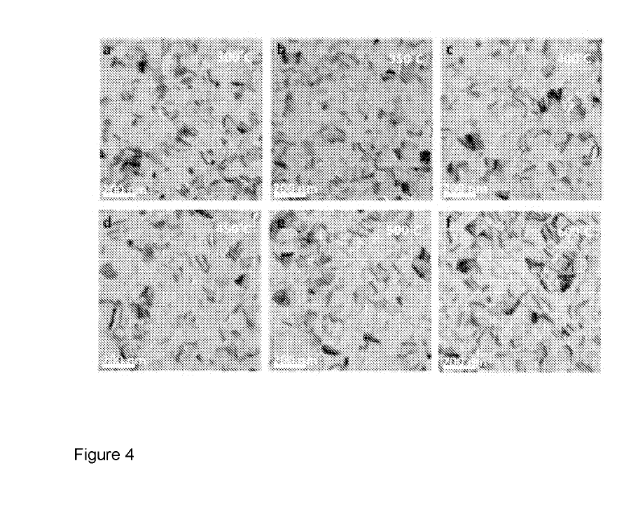

FIG. 4 shows a comparison between the crystallised Co₂FeSi grains after annealing at elevated temperatures.

A method is described to enable the details of the crystallisation processes to be modelled, observed and analysed, to illustrate the optimisation of the crystallisation process in accordance with the principles of the invention. This method, and the apparatus described, is an illustrative example of the principles of the invention. Possible mechanisms for crystal growth during the low-temperature annealing process are discussed, although the method should not be seen as strictly limited by any particular theory in this regard.

Polycrystalline Co₂FeSi thin films were deposited onto both conventional silicon substrates and Si₃N₄ grids for transmission electron microscopy (TEM) at room temperature using a radio-frequency (RF) plasma sputtering system. The 20 nm films, capped with 2 nm of Ru, were annealed in-situ, observed using a double aberration corrected transmission electron microscope. The as-deposited films exhibited a nanocrystalline structure, as shown in FIG. 1a, the initial atomic mixing of which could be varied by changing the deposition conditions. Crystal nucleation was first observed when the samples were heated to 235° C., with FIG. 1c showing an initially crystallised Co₂FeSi grain nucleated in the amorphous-like matrix after annealing at 235° C. for 5 minutes. The grain size diameter is approximately 5 nm, found to be typical for grains annealed for just a few minutes, orientated along the (101) surface plane, as can be seen by the digital diffractogram in FIG. 1d. The schematic atomic structure of the (101) surface is illustrated in FIG. 1e, calculated for a cubic (Fm-3m, L2₁ ordering) crystallite with Co₂FeSi unit cells.

Once the grains have nucleated it is thought that a layer-by-layer growth process occurs in these films. As the crystallites are hexagonal, with the (101) surface facing upwards, the surface facets lie along <111>and <011>. The layer-by-layer growth is therefore expected to occur along the <111>directions.

To explore the growth of the grains in details in situ crystallisation process was observed using both aberration corrected TEM and also selected area electron diffraction. FIG. 2a shows the grain size evolution with annealing time for five representative crystallites (D1-D5) and FIG. 2b the corresponding selected area electron diffraction (SAED). The initial crystallisation speed was found to be almost the same for all crystallites, approximately 2.6±0.1 nm/min. It should also be noted that all the initial nucleation of crystallites occurs within the first 5 minutes of annealing, suggesting that the nucleation is governed by an intrinsic parameter of the film. FIG. 2c shows grain-size evolution during the crystallisation of 5 representative grains, FIG. 2d evolution of (220) peaks and FIG. 2e magnetic moment.

To investigate the structural ordering of the samples, X-ray diffraction (XRD) scans were used to determine explore the evolution of the (220) peaks, known to be related to B2 ordering, with increasing annealing time as shown in FIG. 2d. It can be seen that the films contain a large degree of B2 ordering, which itself has already been shown to lead to a large spin polarisation in Co₂FeSi. It should be empathised, however, that the films may in fact be L2₁ ordered but could not easily be determined in these samples due to their grain size.

To explore the magnetic properties of the films, the ex situ annealed samples were measured using an alternating gradient force magnetometer. The evolution of the magnetic moment as a function of time can be seen in FIG. 2e. It can be seen that the majority of the moment of the sample arises within 120 min. with a steady increase occurring from the as-deposited state due to the steady increase in grain size. The average grain size estimated using the Scherrer equation from FIG. 2d is ˜9.5 nm after 20 min. annealing and is increased up to ˜18 nm after 80˜100 min. annealing. The increase which occurs after 100 minutes occurs due to a restructuring of the grains, as no further growth occurs. Here, the maximum value of M_{S} corresponds to 72% of the theoretical value predicted from the generalised Slater-Pauling curve and is similar to those annealed at 500° C. for 6 h.

After between 100 min. (for D4 and D5) and 120 min. (for D1-D3), the crystallisation speed decreases down to below 0.5 nm/min, which is attributed to the merging processes of the crystallites. This means that the re-aligning of the crystalline axes and planes require almost 5 times more energy than crystallite growth. Since the (101) surface plane is the common plane for the crystallites, the merging process for the crystallites occurs 2-dimensionally (2D). The stripe patterns suggest that such a grain contains mis-aligned surface planes and stress. Here the surface planes of the two merging grains are perfectly aligned along (111) as default. In order to facilitate coalescence the crystallites rotate to adjust the orientation of the (110) plane and then relax the interfacial stress. These merging grains then cover approximately 90% of the surface of the film, after annealing at 235° C. for 3 hours. By dividing the coverage by the density of nucleated crystallites in a HR-TEM image, the average grain size is estimated to be 290 nm in diameter assuming a cylindrical grain shape. This value is three times larger than that measured by the grain-size analysis from the films grown on a TEM grid and ex-situ annealed. However, as the in-situ annealing was carried out at lower magnification compared to the ex-situ annealing a number of initial crystallites are missed or grouped with smaller crystallites, resulting in the larger average grain size.

Here, what is clear is that through utilising in situ aberration corrected microscopy, X-ray diffraction and alternating gradient force magnetometry we have shown that it is possible to prepare highly spin-polarised Heusler alloys films using annealing temperatures compatible with many current technologies. These samples are therefore ideal candidates for use as spin injectors and/or detectors in spintronic devices.

FIG. 3 shows various properties of low temperature annealed Co₂FeSi films. a, TEM image Co₂FeSi film after 3 hours annealing at 235° C. with b, HRTEM image and c, corresponding digital diffractogram of typical grain, d, schematic of the layer-by-layer grain structure, e, hysteresis loop at room temperature.

As shown in FIG. 1a the initial crystallites are hexagonal in the matrix with the (101) zone axis normal to the film surface leading to facets along <111>and <001>. By comparing this schematic crystallite with HR-TEM images we find that, in general, for films annealed at low temperatures the crystallisation speed along <111>(V_{<111>}) is greater than that along <001>(V_{<001>}) whilst being constant relative to one another thus maintain four <111>faces to each crystal. For high annealing temperatures V_{<111>} can become much greater, leading to grains whose shape is more rhombic than square with the formation of <001>facets. This is particularly significant for the case of high-temperature annealing (500° C.), shown in FIGS. 5a-f, as excess thermal energy can lead to a 3D grain rotation causing the (112) plane to face upwards.

In our thin-film samples, the surface planes of the two merging grains are perfectly aligned along (101) orientation. This means that the crystallites rotate to adjust the (111) faces first and then relax the interfacial stress. The re-aligning of the crystalline axes and planes therefore requires almost 5 times more energy than crystallite growth. The rotation of the crystalline axes therefore consumes approximately 85% of the thermal energy introduced by annealing, estimated from the change in the crystallisation speed. The films were annealed at 235° C., which corresponds to the thermal energy of k_{B}T ˜0.044 eV. Hence ˜0.037 eV, 85% of k_{B}T at 235° C., is consumed for the 2D in-plane rotation of the crystallite axes. The remaining energy of ˜0.007 eV is estimated to be the pure crystallisation energy.

To explore the crystallisation in more detail we also annealed the films at higher temperatures, up to 600° C. As already mentioned, it was found that at higher temperatures, above 500° C., some of the grains rotated, leading to the (112) surface facing upwards. This grain rotation most likely occurs due to the excess amount of thermal energy. This means that the grain shapes are much more randomly distributed for the high-temperature annealed films, as can be seen in FIGS. 4a-f. This finding also supports our assumption that the excess energy introduced during annealing induces 3D crystallite rotation, resulting in a random orientation of grains with a wide distribution in facets and rough surfaces.

In the above example we have employed aberration corrected in situ transmission electron microscopy to show that Co₂FeSi thin films can be crystallised at much lower annealing temperatures, around 235° C., whilst still achieving a high spin-polarisation. Through analysing the atomic crystallisation process we show that this low-temperature ordering is achieved by a 2D layer-by-layer growth mode which leads to a significant reduction of over 50% in the formation energy than that of bulk samples. Such a controlled growth mode could also be applied for the other alloys, allowing them to be integrated into future electronic devices.

1. A crystallisation method for an alloy film comprising the steps of:
providing a substrate;
depositing a layer of the alloy film to be crystallised onto the substrate using a physical vapour deposition process to a depth of up to a few hundred nm; and
heating the deposited film at an annealing temperature below 300° C. to effect crystallisation of the alloy film layer.

2. The crystallisation method in accordance with claim 1 wherein the deposited film is heated at an annealing temperature of around 200° C. to 300° C.

3. The crystallisation method in accordance with claim 2 wherein the deposited film is heated at an annealing temperature of around 200° C. to 250° C.

4. The crystallisation method in accordance with claim 1 wherein the deposited film is heated at the annealing temperature for an annealing time of no more than 24 hours.

5. The crystallisation method in accordance with claim 4 wherein the deposited film is heated at the annealing temperature for an annealing time of between 5 minutes and 10 hours.

6. The A crystallisation method in accordance with claim 1 wherein the deposited film is deposited as a thin film using a physical vapour deposition process to a depth of between 3 nm and 25 nm.

7. The crystallisation method in accordance with claim 6 wherein the deposited film is deposited as a thin film using a physical vapour deposition process to a depth of between 5 nm and 20 nm.

8. The crystallisation method in accordance with claim 1 wherein the deposited film is deposited by sputter deposition.

9. The crystallisation method in accordance with claim 1 wherein a capping or other subsequent layer is deposited on top of the layer of alloy film prior to the annealing step.

10. The crystallisation method in accordance with claim 9 wherein a capping or other subsequent layer is deposited comprising one or more noble metals or alloys thereof.

11. The crystallisation method in accordance with claim 1 wherein the deposited layer of the alloy film and the substrate are heated together to anneal the deposited layer of the alloy film in situ on the substrate.

12. The crystallisation method in accordance with claim 11 wherein the substrate is supported on a suitable heating stage to effect heating of the deposited layer of the alloy film and the substrate.

13. The crystallisation method in accordance with claim 1 wherein the substrate comprises a semiconductor device material on which the deposited layer is selected to constitute a functional film.

14. The crystallisation method in accordance with claim 1 wherein the alloy constituting the deposited layer of the alloy film is selected to be a material that crystallises with a face-centred cubic crystal structure.

15. The crystallisation method in accordance with claim 1 wherein the alloy constituting the deposited layer of the alloy film is at least a ternary alloy.

16. The crystallisation method in accordance with claim 1 wherein the alloy constituting the deposited layer of the alloy film is selected to comprise an electromagnetically functional thin film when crystallised.

17. The crystallisation method in accordance with claim 16 wherein the alloy constituting the deposited layer of the alloy film is selected to comprise a ferromagnetic thin film when crystallised.

18. The crystallisation method in accordance with claim 17 wherein the alloy constituting the deposited layer of the alloy film is selected to comprise when crystallised a highly-spin-polarised ferromagnetic thin film.

19. The crystallisation method in accordance with claim 1 wherein the alloy constituting the deposited layer of the alloy film is a ternary Heusler-alloy.

20. The crystallisation method in accordance with claim 19 wherein the alloy is a Co-based ternary Heusler-alloy.

21. A method of fabrication of an alloy layer on a semiconductor device and in particular of fabrication of a functional thin film on a semiconductor device, the method comprising the steps of:
providing a substrate of a semiconductor or spintronic device material;
depositing and crystallising thereon an alloy layer and in particular a functional thin film by the method of claim 1.

22. A semiconductor or spintronic device comprising an alloy layer and in particular a functional thin film that has been deposited and crystallised thereon by the method of claim 1.
